(19) United States
(12) Patent Application Publication
(10) Pub. No.: US 2026/0011654 A1
(43) Pub. Date: Jan. 8, 2026

(54) SEMICONDUCTOR STRUCTURE HAVING ALIGNMENT MARK FOR BONDING BETWEEN WAFERS

(71) Applicant: MACRONIX International Co., Ltd., Hsinchu (TW)

(72) Inventors: Wei-Hung Wang, Hsinchu City (TW); Chih-Hao Huang, Hsinchu Country (TW)

(73) Assignee: MACRONIX International Co., Ltd., Hsinchu (TW)

(21) Appl. No.: 18/762,218

(22) Filed: Jul. 2, 2024

(51) Int. Cl. H01L 23/544; H01L 23/00

(52) U.S. Cl. CPC H01L 23/544; H01L 24/08; H01L 2223/54426; H01L 2224/08145

(57) ABSTRACT

A semiconductor structure including a first structure of a first wafer including a first substrate layer, a first device layer disposed on the first substrate layer, a first bonding layer disposed on the first device layer including a first portion of an alignment mark, and a second structure of a second wafer including a second substrate layer, a second device layer disposed on the second substate layer, a second bonding layer disposed on the second device layer including a second portion of the alignment mark, wherein the first portion of the alignment mark and the second portion of the alignment mark forms the alignment mark configured to provide an alignment for bonding cross the first bonding layer and the second bonding layer. The first device layer or the second device layer may include a three-dimensional NAND flash memory circuit as a part of a storage media with high-performance and high-capacity.

### TECHNICAL FIELD

The disclosure is directed to a semiconductor structure having an alignment mark providing an alignment for bonding between multiple wafers.

### BACKGROUND

A modern semiconductor fabrication process may require two or more wafers to be bonded together. In order to bond together multiple wafers, the wafers have to be aligned properly. Any misalignment of the wafers may cause a bonding failure. To align two or more wafers together in a precise manner, the technique of an alignment mark has been utilized. For example, if two wafers are to be aligned at a certain position, the alignment could be indicated by an alignment mark.

In order to detect the alignment mark, a fabrication facility may utilize a camera or an image sensor. Upon capturing the image, an image processing could be performed to detect the alignment mark based on an expected image pattern. To obtain the image of the alignment mark, a light source has to be applied on the wafer, and the camera or the image sensor has to be able to obtain the reflected light from the wafer. The contrast of the image captured from the camera or the image sensor is related to the positions of each half of the alignment mark.

Therefore, an improved alignment mark that is able to provide a detected image having a better contrast would advance the technology of the semiconductor field.

### SUMMARY OF THE DISCLOSURE

To order to meet the above-described challenges, the disclosure provides a semiconductor structure having an alignment mark providing an alignment for bonding between multiple wafers.

In an aspect, the disclosure is directed to a semiconductor structure which includes but not limited to: a first structure of a first wafer including a first substrate layer, a first device layer disposed on the first substrate layer, a first bonding layer disposed on the first device layer and including a first portion of an alignment mark, and a second structure of a second wafer including a second substrate layer, a second device layer disposed on the second substrate layer, a second bonding layer disposed on the second device layer and including a second portion of the alignment mark, wherein the first portion of the alignment mark in the first structure and the second portion of the alignment mark in the second structure forms the alignment mark configured to provide an alignment for bonding cross the first bonding layer and the second bonding layer, and the first portion of the alignment mark includes a first sub-pattern, the first sub-pattern includes a first pattern and a second pattern which surrounds and is concentric to the first pattern, and the first pattern and the second pattern are separated by an equal distance.

In an aspect, the disclosure is directed to a semiconductor structure including but not limited to: a first structure of a first wafer including a first substrate layer, a first device layer disposed on the first substrate layer, a first bonding layer disposed on the first device layer and including a first portion of an alignment mark, and a second structure of a second wafer including a second substrate layer, a second device layer disposed on the second substrate layer, a second bonding layer disposed on the second device layer and including a second portion of the alignment mark, wherein the first portion of the alignment mark in the first structure and the second portion of the alignment mark in the second structure forms the alignment mark configured to provide an alignment for bonding between the first bonding layer and the second bonding layer, and the first portion of the alignment mark includes a first sub-pattern, the first sub-pattern includes a first side and a first plurality of comb teeth attached to the first side, each of the first plurality of comb teeth is separated by an equal distance.

In order to make the aforementioned features and advantages of the present disclosure comprehensible, exemplary embodiments accompanied with figures are described in detail below. It is to be understood that both the foregoing general description and the following detailed description are exemplary, and are intended to provide further explanation of the disclosure as claimed.

It should be understood, however, that this summary may not contain all of the aspect and embodiments of the present disclosure and is therefore not meant to be limiting or restrictive in any manner. Also, the present disclosure would include improvements and modifications which are obvious to one skilled in the art.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 illustrates a bonding process between two wafers according to an exemplary embodiment of the disclosure.

FIG. 2A illustrates the structure of an alignment mark after a bonding process between wafers is complete according to an exemplary embodiment of the disclosure.

FIG. 2B illustrates the structure of the alignment mark after the bonding process from different perspectives according to an exemplary embodiment of the disclosure.

FIG. 3 illustrates the dimensions of the alignment mark in the top layer and the bottom layer according to an exemplary embodiment of the disclosure.

FIG. 4 illustrates the structure of a sub-pattern of the alignment mark according to a first exemplary embodiment of the disclosure.

FIG. 5 illustrates the line width and the widths between lines of the sub-pattern according to a first exemplary embodiment of the disclosure.

FIG. 6 illustrates the structure of a sub-pattern of the alignment mark according to a second exemplary embodiment of the disclosure.

FIG. 7 illustrates the line width and the widths between lines of the sub-pattern according to a second exemplary embodiment of the disclosure.

FIG. 8 illustrates an alternative embodiment of FIG. 1 according to a third exemplary embodiment of the disclosure.

### DETAILED DESCRIPTION OF DISCLOSED EMBODIMENTS

Reference will now be made in detail to the present exemplary embodiments of the disclosure, examples of which are illustrated in the accompanying drawings. Wherever possible, the same reference numbers are used in the drawings and the description to refer to the same or like parts.

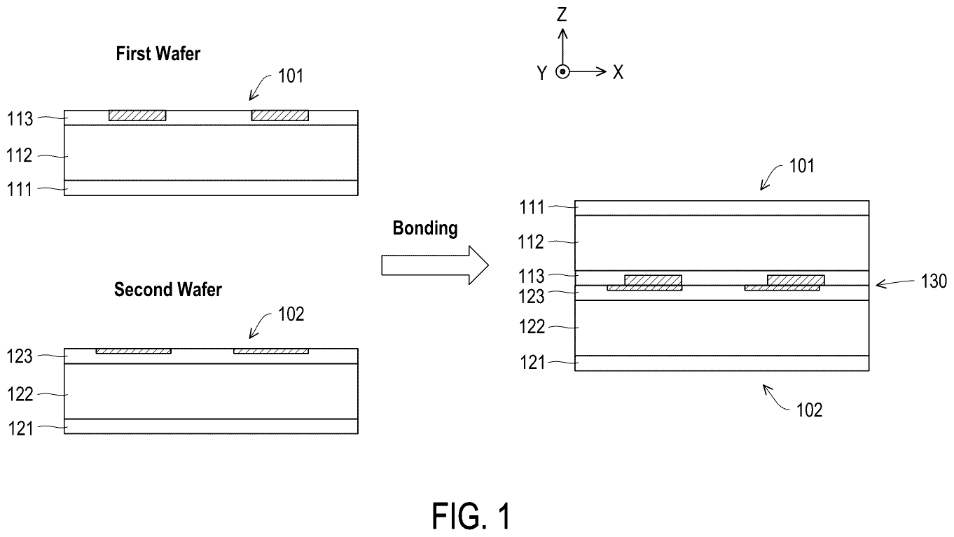

Before describing the structure of the alignment mark, the overall context of the disclosure is provided. A bonding process between two wafers is shown in FIG. 1. As seen in FIG. 1, from a cross sectional view parallel to the Y axis, a first structure 101 from a first wafer is bonded onto a structure 102 from a second wafer forming a semiconductor structure 130. The semiconductor structure 130 could be formed by the first structure 101 of the first wafer flipped upside down and overlayed on top of the second structure 102 of the second wafer.

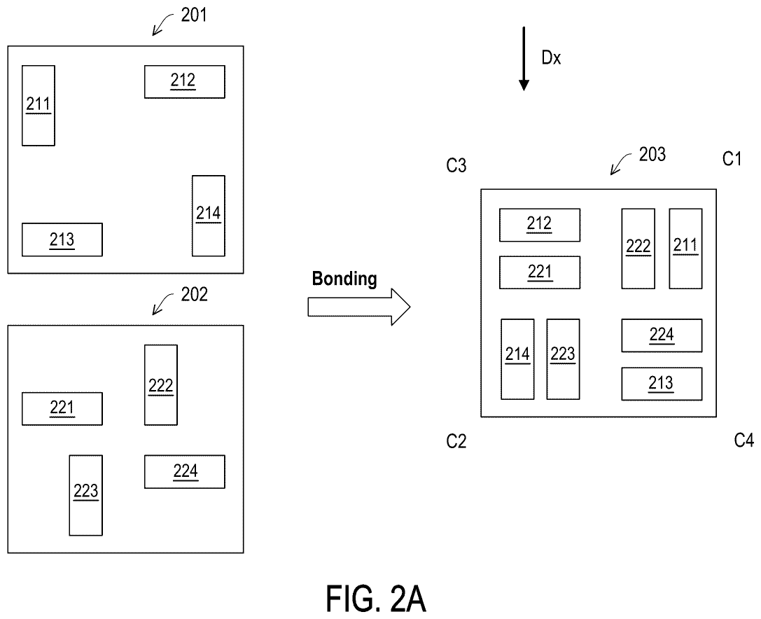

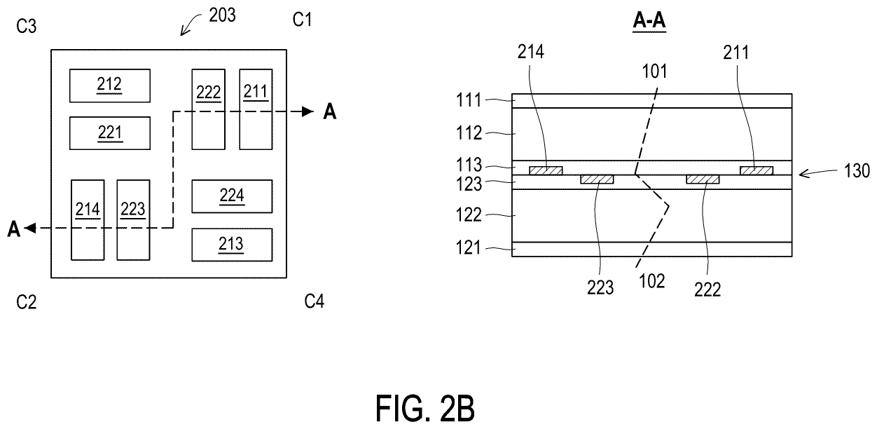

The first structure 101 from the first wafer may include a first substrate layer 111, a first device layer 112 disposed on the first substrate layer 111, and a first bonding layer 113 disposed on the first device layer 112. The first bonding layer 113 may contain a first portion (e.g. 201, FIG. 2A) of an alignment mark. The second structure 102 from the second wafer may include a second substrate layer 121, a second device layer 122 disposed on the second substrate layer, and a second bonding layer 123 disposed on the second device layer 122. The first device layer 112 and the second device layer 122 may contain electrical circuits. The second bonding layer 123 may contain a second portion (e.g. 202, FIG. 2A) of the alignment mark. The first portion (e.g. 201, FIG. 2A) of the alignment mark in the first structure 101 and the second portion (e.g. 202, FIG. 2A) of the alignment mark in the second structure 102 forms one complete alignment mark (e.g. 203, FIG. 2A) configured to provide an alignment for bonding between the first bonding layer 113 and the second bonding layer 123.

The first bonding layer 113 and the second bonding layer 123 may each includes one or more bonding pads. The first structure 101 and the second structure 102 could be bonded together to form the semiconductor structure 130 by, for example, performing direct-bonding, between the one or more bonding pads on both sides of the first bonding layer 113 and the second bonding layer 123. During the process of bonding, the alignment mark would be for providing the alignment to align together the first structure 101 from the first water and the second structure 102 from the second wafer to form the semiconductor structure 130.

The alignment mark provided on the first bonding layer 113 and the second bonding layer 123 is shown in FIG. 2A. As shown in FIG. 2A, in a top view looking down from the top of the Z axis, a first portion 201 of the alignment mark is located on the first bonding layer 113 of the first structure 101 from the first wafer, and the second portion 202 of the alignment mark is located on the second bonding layer 123 of the second structure 102 from the second wafer. The first portion 201 of the alignment mark would include a first plurality of sub-patterns 211, 212, 213 and 214, forming a type of a windmill shape. The second portion 202 of the alignment mark would include a second plurality of sub-patterns 221, 222, 223 and 224, forming another type of a windmill shape. As a part of the alignment and bonding process, the first portion 201 of the alignment mark is to be flipped upside down since the entire first structure 101 is to be flipped around and bonded onto the second structure 102, forming one complete alignment mark 203.

From a cross-sectional view along the Y axis, the first structure 101 from the first water and the second structure 102 from the second wafer may have different thickness. Also, the first portion 201 of the alignment mark in the first bonding layer 113 and the second portion of the alignment mark in the second bonding layer 123 from the cross-sectional view of FIG. 1 may have different heights. Further, from a top view along the Z axis of FIG. 2A, the first portion of an alignment mark and the second portion of the alignment mark does not overlap.

FIG. 2B shows a top view of the alignment 203 looking down from the top of the Z axis and a Y axis view of the semiconductor structure 130 along the A-A line of the alignment mark. As shown in FIG. 2B, along the A-A line of the alignment mark toward the X direction, the sub-patterns are in the order of sub-patterns 214, 223, 222, and 211.

As for the details regarding the structure of the alignment 203, the first portion 201 of the alignment mark 203 may include a first sub-pattern (e.g. 211 or any other sub-patterns 211˜ 214). Assuming that the first sub-pattern is sub-pattern 211, the first portion 201 of the alignment mark 203 may further include a second sub-pattern 214 located across the first sub-pattern along a first diagonal C1-C2 of the alignment mark 203.

Similarly, the second portion 202 of the alignment mark 203 may further includes a third sub-pattern (e.g. 222 or any other sub-patterns 221˜224) which is adjacent to the first sub-pattern 211 and a fourth sub-pattern 223 which is adjacent to the second sub-pattern 214. In this way, the first sub-pattern 211 and the third sub-pattern 222 are symmetrical or similar to the second sub-pattern 214 and the fourth sub-pattern 223 along the first diagonal C1-C2 of the alignment mark 203. Further, it is also evident on FIG. 2A that sub-patterns 212 and 221 and are also symmetrically or similarly patterned relative to sub-patterns 213 and 224 across a second diagonal C3-C4. Subsequently, the alignment mark 203 could be a square shape, and each quadrant of the alignment mark contains sub-patterns belonging to different wafers. For instance, in the quadrant C1, sub-pattern 211 belongs to the first structure 101 from the first wafer while sub-pattern 222 belongs to the second structure 102 from the second wafer. The same applies for the other three quadrants C2, C3 and C4. It should be noted that the shape of the alignment mark 203 could also be other shapes such as a rectangular shape or a triangular shape.

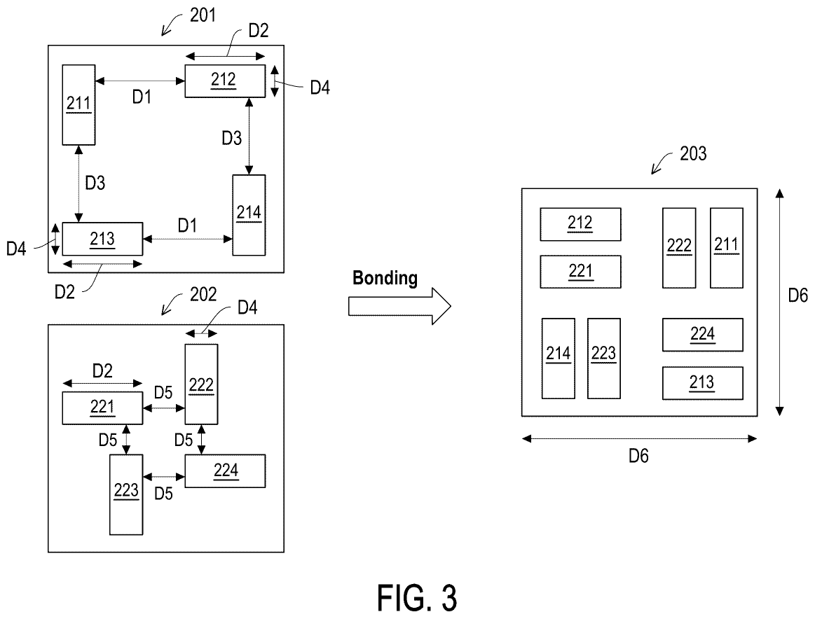

The dimensions of the alignment mark are shown in FIG. 3. Referring to the first portion 201 of the alignment mark 203 as shown in FIG. 3, the distance between the sub-pattern 211 and the sub-pattern 212 as well as the distance between the sub-pattern 213 and the sub-pattern 214 are both D1. The length of each of the sub-patterns 211˜214 is D2. The width of each of the sub-patterns 211˜214 is D4. The distance between the sub-pattern 211 and the sub-pattern 213 as well as the distance between the sub-pattern 212 and the sub-pattern 214 are both D3. In present embodiment, the dimension D6×D6 of the alignment mark is 70 um×70 um, D1 could be 27 um, D2 could be 31 um, D3 could be 27 um, and D4 could be 12 um.

Referring to the first portion 202 of the alignment mark 203 as shown in FIG. 3, the distance between the sub-pattern 221 and the sub-pattern 222 as well as the distance between the sub-pattern 221 and the sub-pattern 223 are both D5. The length of each of the sub-patterns 221˜ 224 is D2. The width of each of the sub-patterns 221˜224 is D4. D5 could be, for example, 8 um.

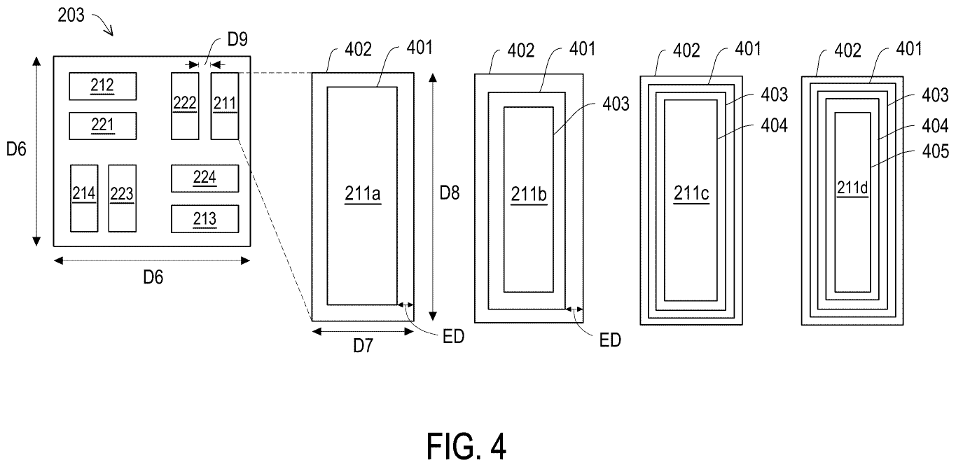

As for the details regarding the structure of each of the sub-pattern 211˜214, 221˜214, FIG. 4 shows the structure of the sub-pattern 211 according to a first exemplary embodiment. For the sub-pattern 211, the structure of the sub-pattern 211 is one of the variations 211a, 211b, 211c, or 211d. For the sub-pattern structure 211a, it includes a first pattern 401 and a second pattern 402 which surrounds and is concentric to the first pattern 401, and the first pattern 401 and the second pattern 402 are separated by an equal distance ED along the X direction or along the Z direction. For the sub-pattern structure 211b, it is identical to the sub-pattern structure 211a except that it includes a third pattern 403 which is surrounded by and is concentric to both the first pattern 401 and the second pattern 402. The first pattern 401 and the second pattern 402 are separated by an equal distance ED along the X direction or along the Z direction, and the second pattern 402 and the third pattern 403 are also separated by the equal distance at all locations.

For the sub-pattern structure 211c, it is identical to the sub-pattern structure 211b except that it includes a fourth pattern 404 which is surrounded by and is concentric to the first pattern 401 and the second pattern 402 and the third pattern 403, and all of the first, second, third, and fourth pattern 404 are separated by the equal distance ED along the X direction or along the Z direction. For the sub-pattern structure 211d, it is identical to the sub-pattern structure 211c except it has even one more concentric rectangle inside of the fourth pattern 404. It should be noted that the disclosure may include the embodiment of a sub-pattern having more than 4 concentric rectangles, but the disclosure only shows 4 of such variations. Furthermore, each of the sub-patterns 211˜214, 221˜224 may have the same structure as the sub-pattern 211 except that some of the sub-patterns are oriented toward different directions. In addition, different sub-patterns 211˜214, 221˜224 may have different numbers of concentric rectangles.

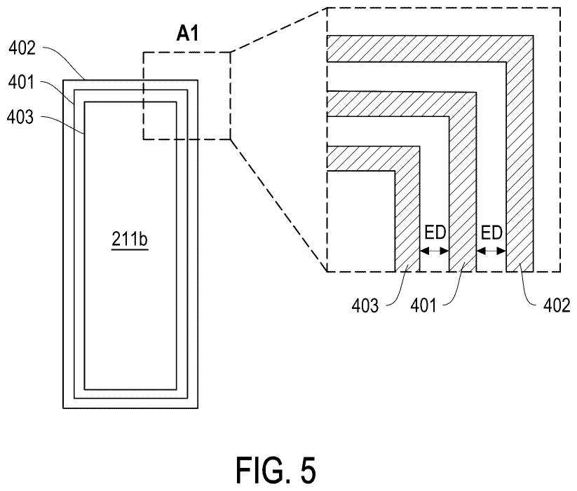

FIG. 5 shows the structure of area A1 of the sub-pattern structure 211b with further details according to the first exemplary embodiment. In the area A1 of the sub-pattern structure 211b, it includes a first pattern 401, a second pattern 402, and a third pattern 403 which is identical to the sub-pattern structure 211b of FIG. 4. The line width of each of the first pattern 401, the second pattern 402, and the third pattern 403 is equal to the gap between each of the lines of the first pattern 401, the second pattern 402, and the third pattern 403. In present embodiment, the distance ED between the first pattern 401 and the second pattern 402 is 0.5 um. The distance ED between the first pattern 401 and the third pattern 403 is also 0.5 um. Moreover, each of the line widths of the first pattern 401, the second pattern 402, and the third pattern 403 is also 0.5 um. In other alternative embodiments, the distance ED could be adjusted basing on the limitation of process generation or user's requirement.

It should be apparent to an ordinary person skilled in the art that the structure described for A1 is also applicable to other parts of the sub-pattern structures as well as to other aforementioned sub-pattern structures. Furthermore, the disclosure described for the structure of the sub-pattern 211 is also applicable to sub-patterns 212˜214, 221˜224. As described previously, under the circumstance of the line widths or the gaps between lines being less than or equals to 0.5 um, the disclosure of the design of the alignment mark is able to improve the contrast of detected alignment mark image when the line width or the distance between lines is less than or equals to 0.5 um.

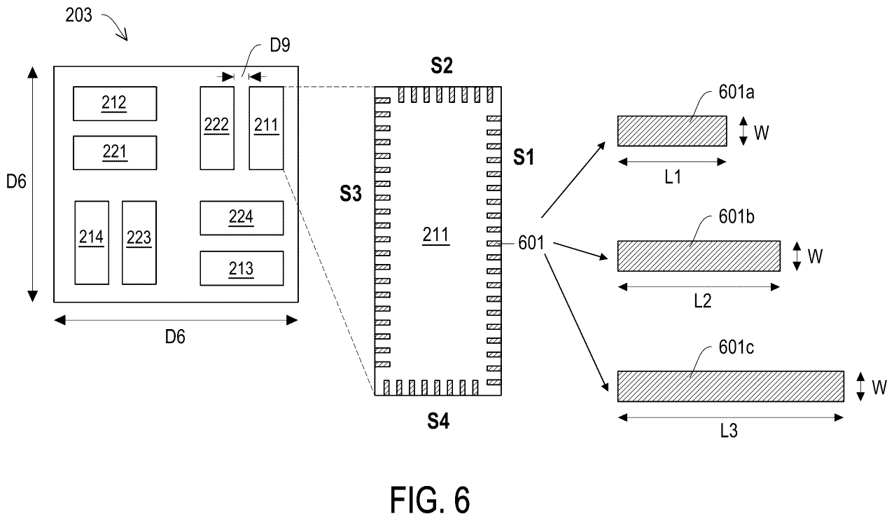

FIG. 6 shows the structure of the sub-pattern 211 according to a second exemplary embodiment. As shown in FIG. 6, the sub-pattern 211 includes a first structure having four sides S1, S2, S3, and S4, and each side of the sub-pattern 211 has a line width. A side of the sub-pattern is one of S1, S2, S3, and S4 without including the comb teeth. On each of the four sides of the lines of the sub-pattern 211, a plurality of comb teeth is attached to the line of each side of the four sides of the sub-pattern 211. In particular, as shown in FIG. 6, the sub-pattern 211 includes a first side S1 and a first plurality of comb teeth are attached to the first side S1. Moreover, each of the first plurality of comb teeth could be separated by an equal distance in Y direction. Further, the sub-pattern 211 may also include a second side S2 which is physically connected to the first side S1 and includes a second plurality of comb teeth, each of the second plurality of comb teeth may also be separated by the equal distance in X direction.

A single comb tooth of the above-described comb teeth may have different lengths. For instance, the comb tooth 601 may have three variations, the first variation 601a being a comb tooth having a width W and a length L1, the second variation 601b being a comb tooth having a width W and a length L2, and the third variation 601c being a comb tooth having a width W and a length L3. More specifically, the width W could be 0.5 um, the length L1 could be 2 um, the length L2 could be 3 um, and the length L3 could be 4 um. According to one exemplary embodiment, all comb teeth of all four sides could be identical in length which is either L1 or L2 or L3. In another exemplary embodiment, different sides of the sub-structure 211 may have different lengths of comb teeth.

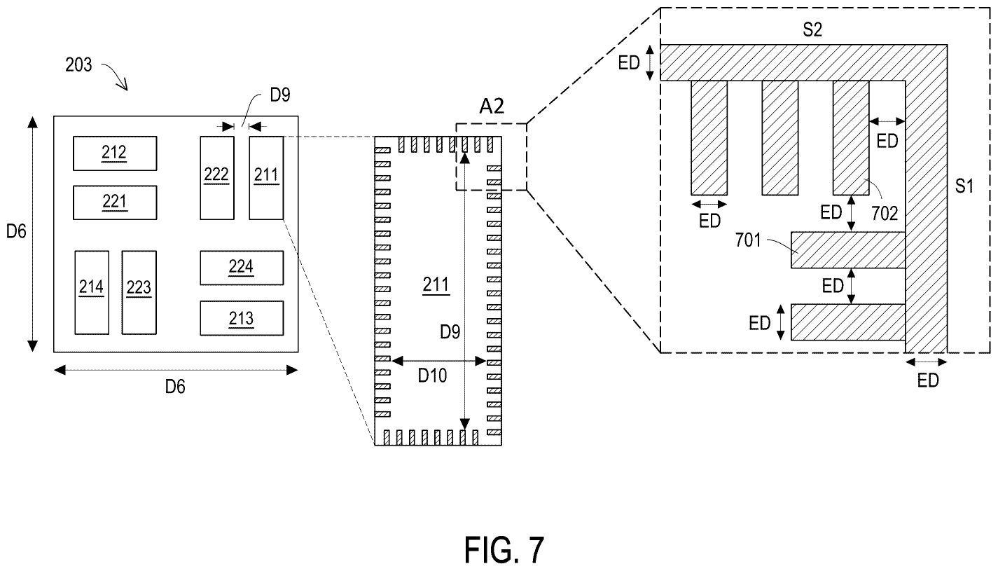

FIG. 7 shows the structure of area A2 of the sub-pattern structure 211b with further details according to the second exemplary embodiment. In the area A2, the line width of the first side S1 is W, and the line width of the second side S2 is also W. Moreover, the width of each tooth of the first plurality of comb teeth attached to the first side S1 is W as well as the width of each tooth of the second plurality of comb teeth attached to the second side S2. The distance between each of the comb teeth in the first plurality of comb teeth and the distance between each of the comb teeth in the second plurality of comb teeth is also W. Furthermore, a first comb teeth 701 of the first plurality of comb teeth is separated from a second comb teeth 702 of the second plurality of comb teeth by the distance W. The distance is less than or equal to 0.5 um.

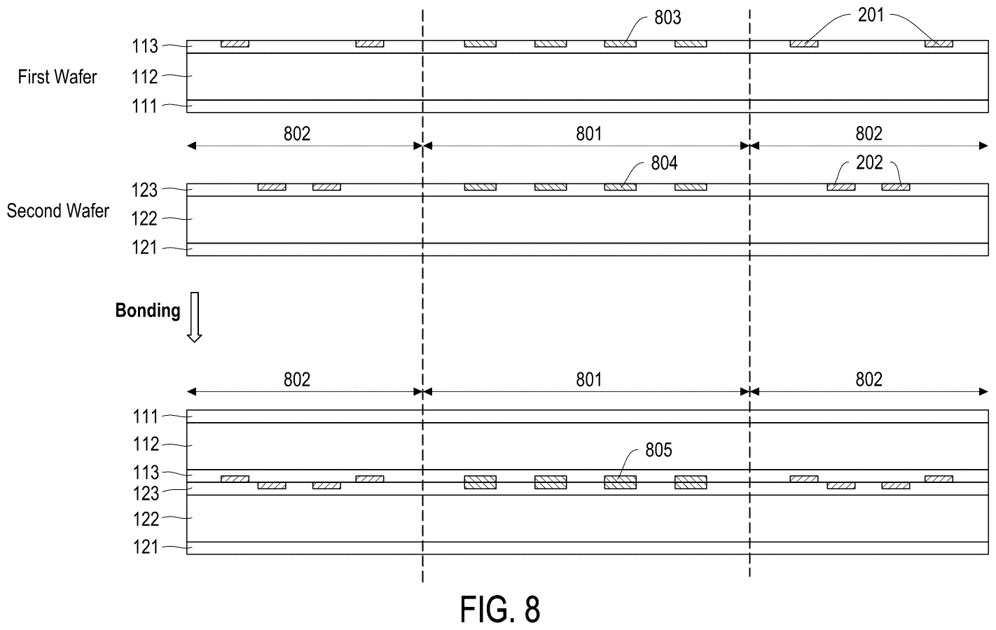

FIG. 8 shows an embodiment similar to the embodiment of FIG. 1. For the embodiment of FIG. 8, the first bonding layer 113 of first water has two regions, one or more first regions 801 and one or more second regions 802. The first region 801 as shown in FIG. 8 has a plurality of bonding pads 803 and each of the second regions may include a half portion 201 of the alignment mark 203. Similarly, the second bonding layer 123 of the second water also has two regions, one or more first regions 801 and one or more second regions 802. The first region 801 has a plurality of bonding pads 804 and each of the second regions may include a half portion 202 of the alignment mark 203.

After the structure of the first wafer has been directed bonded onto the structure of the second water to form a semiconductor structure 130, the first region 801 of the semiconductor structure 130 includes a plurality of bonding pads 803 from the first wafer and a plurality of bonding pads 804 from the second wafer directly bonded to each other as bonded bonding pads 805. In general, the first region 801 is for signal or power connections between the device layers (e.g. 112 and 122) across different wafers so that the bonding pads 803 804 have to be directly bonded together. Further, from a top view or a bottom view along the Z axis, the sub-patterns of the first portion (e.g. 201) of the alignment mark 203 and the sub-patterns of the second portion (e.g. 202) of the alignment mark 203 do not overlap from one another. In other words, patterns of the first portion 201 of the alignment mark 203 and patterns of the second portion 202 of the alignment mark 203 do not overlap with each other from a perspective which is perpendicular to a bonding interface between or parallel to the first bonding layer 113 and the second bonding layer 123. Further, both the minimum line width of the bonding pads 803 804 805 and the minimum line width of the alignment mark 203 is less than or equals to 0.5 um.

In view of the aforementioned-descriptions, the present disclosure is suitable for being used in any electronic circuits such as a three-dimensional NAND flash memory circuit as a part of a storage media with high-performance and high-capacity. The alignment mark structure described in this disclosure is able to increase the contrast of detected alignment mark images and is thus able to reduce bonding failures caused by alignment errors.

No element, act, or instruction used in the detailed description of disclosed embodiments of the present application should be construed as absolutely critical or essential to the present disclosure unless explicitly described as such. Also, as used herein, each of the indefinite articles “a” and “an” could include more than one item. If only one item is intended, the terms “a single” or similar languages would be used. Furthermore, the terms “any of” followed by a listing of a plurality of items and/or a plurality of categories of items, as used herein, are intended to include “any of”, “any combination of”, “any multiple of”, and/or “any combination of multiples of” the items and/or the categories of items, individually or in conjunction with other items and/or other categories of items. Further, as used herein, the term “set” is intended to include any number of items, including zero. Further, as used herein, the term “number” is intended to include any number, including zero.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A semiconductor structure comprising:
a first structure of a first wafer comprising:
a first substrate layer,
a first device layer disposed on the first substrate layer,
a first bonding layer disposed on the first device layer and comprising a first portion of an alignment mark, and
a second structure of a second wafer comprising:
a second substrate layer,
a second device layer disposed on the second substate layer,
a second bonding layer disposed on the second device layer and comprising a second portion of the alignment mark, wherein
the first portion of the alignment mark in the first structure and the second portion of the alignment mark in the second structure forms the alignment mark configured to provide an alignment for bonding cross the first bonding layer and the second bonding layer, and
the first portion of the alignment mark comprises a first sub-pattern, the first sub-pattern comprises a first pattern and a second pattern which surrounds and is concentric to the first pattern, and the first pattern and the second pattern are separated by an specific distance.

2. The semiconductor structure of claim 1, wherein first sub-pattern further comprises a third pattern which surrounds and is concentric to the second pattern, and the second pattern and the third pattern are separated by the specific distance.

3. The semiconductor structure of claim 2, wherein the first pattern, the second pattern, and the third pattern are rectangular shapes.

4. The semiconductor structure of claim 3, wherein the specific distance is less than or equals to 0.5 micrometer.

5. The semiconductor structure of claim 4, wherein each of line widths of the first pattern, the second pattern, and the third pattern is the specific distance.

6. The semiconductor structure of claim 1, wherein the first portion of the alignment mark further comprises a second sub-pattern located across the first sub-pattern along a first diagonal of the alignment mark.

7. The semiconductor structure of claim 6, wherein the second portion of the alignment mark further comprises a third sub-pattern which is adjacent to the first sub-pattern and a fourth sub-pattern which is adjacent to the second sub-pattern.

8. The semiconductor structure of claim 1, wherein
the first structure comprises a first region and a second region,
the second structure comprises the first region and the second region,
the first region of the first structure comprises a first plurality of bonding pads, and
the first region of the second structure comprises a second plurality of bonding pads which are directly bonded with the first plurality of bonding pads.

9. The semiconductor structure of claim 8, wherein
the second region of the first structure comprises the first portion of the alignment mark,
the second region of the second structure comprises the second portion of the alignment mark, and
patterns of the first portion of the alignment mark and patterns of the second portion of the alignment mark do not overlap with each other from a perspective which is perpendicular to a bonding interface between the first bonding layer and the second bonding layer.

10. The semiconductor structure of claim 1, wherein the alignment mark has a square shape, and each quadrant of the alignment mark contains sub-patterns belonging to different wafers.

11. A semiconductor structure comprising:
a first structure of a first wafer comprising:
a first substrate layer,
a first device layer disposed on the first substrate layer,
a first bonding layer disposed on the first device layer and comprising a first portion of an alignment mark, and
a second structure of a second wafer comprising:
a second substrate layer,
a second device layer disposed on the second substate layer,
a second bonding layer disposed on the second device layer and comprising a second portion of the alignment mark, wherein
the first portion of the alignment mark in the first structure and the second portion of the alignment mark in the second structure forms the alignment mark configured to provide an alignment for bonding between the first bonding layer and the second bonding layer, and
the first portion of the alignment mark comprises a first sub-pattern, the first sub-pattern comprises a first side and a first plurality of comb teeth attached to the first side, each of the first plurality of comb teeth is separated by an first distance.

12. The semiconductor structure of claim 11, wherein the first sub-pattern further comprises a second side which is physically connected to the first side and comprises a second plurality of comb teeth, each of the second plurality of comb teeth is separated by the first distance.

13. The semiconductor structure of claim 12, wherein a first comb teeth of the first plurality of comb teeth is separated from a second comb teeth of the second plurality of comb teeth by the first distance.

14. The semiconductor structure of claim 13, wherein the first distance is less than or equal to 0.5 micrometer.

15. The semiconductor structure of claim 14, wherein each line widths of the first side and the second side is the first distance.

16. The semiconductor structure of claim 11, wherein the first portion of the alignment mark further comprises a second sub-pattern located diagonally across the first sub-pattern along a first diagonal.

17. The semiconductor structure of claim 16, wherein the second half of the alignment mark further comprises a third sub-pattern which is adjacent to the first sub-pattern and a fourth sub-pattern which is adjacent to the second sub-pattern.

18. The semiconductor structure of claim 11, wherein
the first structure comprises a first region and a second region,
the second structure comprises the first region and the second region,
the first region of the first structure comprises a first plurality of bonding pads, and
the first region of the second structure comprises a second plurality of bonding pads which are directly bonded with the first plurality of bonding pads.

19. The semiconductor structure of claim 18, wherein
the second region of the first structure comprises the first portion of the alignment mark,
the second region of the second structure comprises the second portion of the alignment mark, and
patterns of the first portion of the alignment mark and patterns of the second portion of the alignment mark do not overlap with each other from a perspective which is perpendicular to a bonding interface between the first bonding layer and the second bonding layer.

20. The semiconductor structure of claim 11, wherein the alignment mark has a square shape, and each quadrant of the alignment mark contains sub-patterns belonging to different wafers.
